(19) United States
(12) Patent Application Publication
(10) Pub. No.: US 2012/0183888 A1
(43) Pub. Date: Jul. 19, 2012

(54) PHOTOPOLYMER FOR VOLUME HOLOGRAPHIC RECORDING AND ITS PRODUCTION PROCESS

(76) Inventors: Sergio Assumpção Oliveira, S.P. (BR); Martin MÜLLER, Zurich (CH)

(21) Appl. No.: 13/352,723

(22) Filed: Jan. 18, 2012

(30) Foreign Application Priority Data
Jan. 19, 2011 (BR) PI110000786

(51) Int. Cl. G03F 7/004

(52) U.S. Cl. 430/2

(57) ABSTRACT

The present invention refers to the manufacturing method of a holographic film and its development; the compositions of the films used in this invention are substantially solid and applied on a substrate in film or glass form; the photopolymerizable layer consists of a thickness of about 10 to 100 μm (microns), consisting of: a) 70% to 90% over the total weight of a thermoplastic “polymer”, b) 10% to 30% over the total weight of a preferably mono-functional photopolymerizable monomer reactive to light and, c) 1% to 10% per weight of an expansion agent that when heated at a minimum of 75° C. produces a gas in the unhardened or monomer polymerized areas of the hologram; furthermore, the composition contains a photoinitiator system sensitive to visible light, surfactants, plasticizers, etc.; photopolymerizable monomers used in this invention contains at least one part unsaturated ethylene with a boiling temperature equal or higher than 100° C.

### BACKGROUND OF THE INVENTION

1. Field of the Invention

The present invention refers to a new material for volume holographic recording by means of recording of the light distribution intensity in a standard interference where a holographic polymeric image is formed and the intensity is later amplified through a thermal process.

2. Description of Related Art

Photopolymers are notedly used in the safety seal industry to avoid falsifications, holographic screens and optical elements. The current materials are of difficult process in terms of using long thermal process periods and development by ultraviolet light with special film lamination with monomers to obtain high efficiencies.

Until now, no material presents an efficient, simple and low cost solution for obtaining high efficiency diffraction for volume, transmission or reflection holograms.

Holography is a form of recording lines of optical interferences in a photosensitive material.

A hologram is characterized by its diffraction efficiency, which is the percentage of diffracted incident light on the diffraction network by its thickness. According to the “Coupled wave theory” developed by Kogelnik (H. Kogelnik. Coupled Wave Theory for Thick Hologram Gratings, Bell Syst. Tech J., 48, 2909-2947. 1969), the relationship between diffraction efficiency, hologram thickness, wavelength of incident radiation and angle of incidence of the same is useful in the evaluation of diffraction efficiency.

The modulation of the refraction index is the measurement required to obtain an evaluation of the refraction index, and it is measured by the difference of the refraction index between the recorded lines or not by polymerization of monomers in the interference lines of the hologram. This index modulation is best calculated forming a hologram (reflection hologram for example) and knowing the thickness and efficiency of diffraction. The extraordinary index obtained by the present invention is visually discernible by the characteristics similar to the dichromated gelatin hologram, observing a difference in the modulation index only obtained by the formation of micro or nano gas bubbles in the unrecorded region (polymerized) of interference of the hologram.

Several patents were applied on solid photopolymerizable compositions usable for obtaining holograms. For instance, patent U.S. Pat. No. 5,098,803 is known to refer to a solid composition used between plastic sheets consisting of a mixture of a structural polymer, an unsaturated ethylene monomer and, additionally, a plastifier, and the refraction index is obtained from the difference between the polymer and monomer indices and the result can be improved by prolonged heating as in patent U.S. Pat. No. 572,590 and with lamination on the polymer layer with a diffusion layer on a plastic sheet support to increase the refraction index of the hologram by increasing the width of the spectral band produced by the hologram. This process is expensive because of the need to expose the film to ultraviolet light, to thermal process for a long period of time and the need for a second lamination of a photopolymer diffusion film consisting of monomers to increase the width of the interference fringes and posterior prolonged heat treatment of over 60 minutes and also the extensive application of ultraviolet light.

Application of the patent U.S. 2008/0311483 A1 is also known, in which it describes a system based on polyurethane comprising a polyisocyanate and polyol matrix in which a radical polymerization monomer is exposed to actinic radiation, forming fringes of refraction index on the site and consequently holograms. This system is difficult to produce because of the curing nature of polyurethane. Furthermore, these materials were not designated to work as thermoplastics for application by “heat embossing” to form a fine holographic reflection film.

### SUMMARY OF THE INVENTION

The present invention, in this sense, comes to provide a new holographic film with efficiency similar to that of dichromated gelatin but with a higher sensitivity. Still with the objective of avoiding the previous inconveniences through the formulation of a photopolymer comprising a thermoplastic polymer soluble in organic solvents in the proportion of 70% total weight and a high refraction index monomer in the proportion of 10% to 30% total weight, with this emulsion forming the solid part to be applied as covering in solvent around 35 μm thickness on a polyester film base or similar.

With the use of a photoinitiator system with light visible to laser, the system initially records a volume hologram suitable for image inspection and posterior thermal amplification. This initial recording forms high-density regions of polymerized monomers and low density regions occupied by the structural polymer. In this high-density regions of polymerized monomers the formation of nanoscopic bubbles that are formed in the other polymer region is inhibited, evidently obtaining a large refraction index difference. The size of the bubbles obtained is also limited due to the barrier of polymers resulting from the polymerization of monomers. These bubbles similar to the dichromate gelatin (DCG) hologram are formed “in situ” after the formation of the hologram through a thermal expansion agent that decomposes at a certain temperature range (120 -160° C.) releasing a gas, such as nitrogen (N2), at molecular level, which agglutinates with other gas molecules forming micro-bubbles in the heated and softened thermoplastic region. The formation of bubbles is inhibited in the polymerized monomer regions, forming a volume hologram. The initial index difference between the polymer and monomer is increased by the artificiality of the index reduction of the structural polymer region by bubbles.

### DETAILED DESCRIPTION OF THE INVENTION

The present invention refers to the method of manufacturing a holographic film and its development process. The compositions of films used in this invention are substantially solid and applied in a substrate in the form of film or glass. The photopolymerizable layer consists of a thickness of about 10 to 100 um (microns), consisting of:

a) 70% to 90% over the total weight of a thermoplastic “polymer”,

b) 10% to 30% over the total weight of a photopolymerizable monomer, preferably mono-functional and reactive to light and,

c) 1% to 10% per weight of an expansion agent that when heated to at least 75° C. produces a gas in the unhardened or monomer polymerized areas of the hologram.

Furthermore, the composition contains a photoinitiator system sensitive to visible light, surfactants, plasticizers, etc. Photopolymerizable monomers used in this invention contain at least one part unsaturated ethylene with a boiling temperature equal or higher than 100° C.

The composition preferably contains at least one photoinitiator system suitable for the formation of holograms and also a photoinitiator for a post-exposure of the film to visible light, for example, 405 nm to complete the polymerization of the acrylate monomers.

Possible unsaturated acrylate monomers preferably mono-functional consisting of, for example, acrylates or methacrylates like methyl acrylate, ethyl acrylate, isobornyl acrylate, phenyl acrylate, p-chlorophenyl acrylate, p-bromophenyl acrylate and preferably O-phenylphenoxyethyl acrylate, AGISYN® 2871.

Vinyl esters such as VEOVA® 9 or VEOVA® 10 of Shell Company can be used. Aromatic vinyl such as N-Vinylpyrrolidone and 9-vinylcarbazole can also be used. Also, radical stabilizers like hydroquinones and quinones can be used for conservation.

Photoinitiators can be activated by light and being radical polymerization of the monomer, they can be monomolecular (Type I) or bimolecular (Type II) and commercial systems like in type I aromatic ketones, e.g. benzophenone and type II, like benzoin, phosphine oxides, mixtures of dyes and amine co-initiators, such as new methylene blue, azure C, methylene blue, and also commercial initiators Spectra H-Nu.

Dimers of 2,4,5-triphenylimidazolyl are also suitable photoinitiators, as discussed in patent U.S. Pat. No. 3,749,185.

Compounds formed by ionic pairs of cyanine and triphenyl butyl borate dyes such as 3,3′-Dibutylthiacarbocyanine iodine and butyryl choline butyltriphenylborate (Borate V) are especially suitable for this invention, as discussed in patent U.S. Pat. No. 4,842,980. Not particularly wanting to comply with any theory of the polymerization mechanism, we discovered that these compounds are especially useful for the sensitization of multicolored holograms due to the extreme flexibility of the choice of wavelength and also the formation capacity of a fine polymerization structure of a quarter wavelength necessary to obtain reflection holograms, which the initiator Irgacure® 784, for example, has difficulty in obtaining, even if the quality of the polymer is not efficient for the industrial polymer formation process, we observed that this system fits perfectly in the formation of holograms, as long as the matrix polymer and monomer are kept at low acidity and preferably in an apolar medium.

The expansion agent used in this invention can be any element stable at room temperature and at exposure actinic radiation, that is, does not decompose in gas forming bubbles during exposure and produces them only in the region not exposed to light when decomposed at a temperature of 75° C.-160° C. From the many expansion agents available, elements that can be used in this invention are, for example, oxalate salts, inorganic acids like carbonic acids, organic compounds like 4-ketobenzotriazine, expansion agents like chlorinated hydrocarbons and especially suitable are agents like 1,1″-Azobis (cyanocyclohexane), Dupont® VAZO® 88, VAZO® 67, VAZO® 64 and VAZO® 52.

The thermoplastic polymer used in this invention has a softening temperature higher than 50° C. and rigidity or molecular weight sufficient to form a solid base when mixed to the monomer and other components. Copolymers like vinylidene/methacrylate chloride and vinylidene/vinyl-acetate chloride can be used at the same time as an oxygen barrier enabling the polymerization of monomers. CAB (cellulose acetate butyrate), polymethyl methacrylates, polyvinyl butyrate and formal polyvinyl can be used. CAB® 531-1 of Eastman® Company with high compatibility with the monomer AgiSyn 2871 is particularly usable in this invention. The elements of this invention correspond to a layer of a solid and transparent composition applied on an also transparent substrate, preferably a plastic film resistant to thermal development temperature (100° C. - 165° C.), also able to include a thin layer between the holographic polymer and the plastic film of a “releasing” agent for application of the hologram as a “hot stamping foil” or hot transfer of the holographic image of the photopolymer film to a substrate at the same time, eliminating this base to only have a thin layer of photopolymer applied to a substrate with the hologram; this application can be used at the same time to apply and develop the hologram. A substrate especially suitable for this invention is the polyester.

The invention is prepared by the dissolution of elements in a volatile solvent like methyl ethyl ketone or ethyl acetate and spread as cover in the plastic support by a cover bar, for instance. The composition can contain a plasticizer as adjunct to improve the internal diffusion of the monomer in the solid emulsion.

As preparation of the films, the covering solution is prepared by adding the components in solvent until complete dissolution. The solvent used, such as methyl ethyl ketone (MEK) for instance, is used as a covering solution with 30% to 40% in solid part. In a 75 μm polyester film through a steel cover bar of 140 μm (no. 56) the emulsion is covered and left to dry for 15 minutes. A 50 um polyester sheet is laminated on the covering to protect it from air. For use, the element of this invention is exposed to actinic radiation of a coherent laser forming a hologram. The exposed element containing a reflection or transmission hologram is heated through a laminator, infrared radiation, thermal printers or through other means for a short period for time at a temperature between 75° C. to 165° C. to vaporize the element contained to form bubbles in the anti-node regions, at the same time softening the surrounding polymeric stratum. The expansion agent can also have the property of completing the polymerization of monomers not polymerized in the recording of the hologram. After the thermal process, a post-illumination helps clarify the emulsion of the sensitive dyes used.

The following examples will demonstrate the scope of this invention, not limited to the elements described:

### EXAMPLE I

A solution of 20 ml of methyl-ethyl-ketone (MEK) is prepared containing 3 g of CAB®-531-1, 1.5 ml of O-phenylphenoxyethyl acrilate AgiSyn® 2871, 25 mg of Borate V B001F—Spectra Group Limited, 0.5 mg of the dye 3.3′-Dibutylthiacarbocyanine iodine, 20 mg of Irgacure® 819 and 200 mg of VAZO® 88. The solution is applied to a polyester substrate of 75 um through a 140 um cover bar forming a 35 um covering after drying for 20 minutes. A 50 um polyester film is added to this emulsion as covering through lamination. For use, this film cover is removed and the emulsion is laminated to the glass plate to give movement stability and record a reflection hologram through a DPSS laser of 532 nm with exposure of 1 m#/cm² for 30 seconds, where clarification of the hologram recording is observed in real time, after which it is fixed and clarified by exposure to a 50 W dichroic lamp for 5 minutes at a distance of 15 cm. This hologram is developed by passing a hot roll laminator at 150° C. obtaining a highly amplified image with brilliance similar to the ‘DCG″ method.

### EXAMPLE II

A 40 ml solution of methyl-ethyl-ketone (MEK) is prepared containing 3 g of VINNOL® E 15/45 (WACKER), 1.5 ml of O-phenylphenoxyethyl acrylate AgiSyn® 2871, 50 mg of Irgacure® 784 and 200 mg of VAZO® 88. The solution is applied to a 75 um polyester substrate by a 140 um cover bar forming a cover of 15 um after drying for 20 minutes. A 50 um polyester film is laminated on the emulsion as a covering. For use, this film cover is removed and the emulsion laminated to an acrylic plate to give movement stability and record a transmission hologram through a DPSS laser of 532 nm with an exposure of 1 mW/cm² for 90 seconds where clarification is observed on the hologram recording in “real time”, after which it is fixed and clarified by an exposure to a 50 W dichroic lamp for 5 minutes at a distance of 15 cm. This hologram is developed by passing a hot roll laminator at 150° C. obtaining a highly amplified image with brilliance similar to the ‘DCG″ method. After development, the emulsion is laminated by hot roll laminator at 150° C. on a substrate of paper with the polymer surface in direct contact and the polyester plastic film is removed leaning a thin layer with the intact hologram printed on the paper substrate, therefore forming a hot safety holographic print. This procedure can be repeated with reflection holograms.

It is to be understood that the above-described embodiments are illustrative of only a few of the many possible specific embodiments, which can represent applications of the principles of the invention. Numerous and varied other arrangements can be readily devised in accordance with these principles by those skilled in the art without departing from the spirit and scope of the invention.

1. A photopolymer for volume holographic recording through refraction index difference, characterized by the presence of an expansion agent that forms gas in micro-bubbles in unexposed regions of the holographic fringe, comprising per weight: a) 70% to 90% of a thermoplastic “polymer’, b) 10% to 30% of a preferably mono-functional photopolymerizable monomer reactive to light, c) 1% to 10% of an expansion agent that when heated at a minimum 75° C. produces a gas and forms bubbles in the unhardened or monomer polymerized areas of the hologram and, d) 0.1% to 1% of a photoinitiator that activates the polymerization of the said monomer with exposure of the actinic radiation.

2. The photopolymer for volume holographic recording according to claim 1, wherein the photoinitiator comprises the association of ionic pairs of cyanine and triphenyl butyl borate or tetrabutyl borate or even dibutyl phenyl borate dyes.

3. The photopolymer for volume holographic recording according to claim 1, wherein the thermoplastic is selected from the group consisting of vinylidene chloride, vinylidene/methacrylate chloride and vinylidene/vinylideneacetate chloride and cellulose acetate butyrate.

4. The photopolymer for volume holographic recording according to claim 1, wherein the monomer comprises acrylates or methacrylates selected from the group consisting of methyl acrylate, ethyl acrylate, isobornyl acrylate, phenyl acrylate, p-chlorophenyl acrylate, p-bromophenyl acrylate and preferably O-phenylphenoxyethyl acrylate, AGISYN® 2871, VEOVA® 9 or VEOVA® 10 of Shell Company, aromatic vinyl like N-Vinylpyrrolidone and 9-vinylcarbazole.

5. The photopolymer for volume holographic recording according to claim 1, wherein the expansion agent is selected from the group consisting of oxalate salts, inorganic acids, 4-ketobenzotriazine, 1,1″-Azobis (cyanocyclohexane), Dupont®, VAZO® 88, VAZO® 67, VAZO® 64 and VAZO® 52.

6. A production process of a photopolymer for volume hologram recording through which the exposed element containing a reflection or transmission hologram, according to claim 1 comprising the step of heating by a laminator, infrared radiation, thermal printers or by other means for a short period of time at a temperature between 75° C. to 165° C. to vaporize the element contained to form bubbles in the anti-nodal regions, at the same time softening the surrounding polymeric stratum.

7. The production process of a photopolymer for volume hologram recording through which the exposed element containing a reflection or transmission hologram, according to claim 1 comprising the step of transferring the photopolymer for volume hologram recording to another substrate through heating to a temperature between 120° C. and 165° C. and pressure with the polymer surface in direct contact with the transfer surface, and recording the holographic film after removal of the original polyester film used as a carrier.
